(19) United States
(12) Patent Application Publication
(10) Pub. No.: US 2009/0053017 A1
(43) Pub. Date: Feb. 26, 2009

(54) STORAGE AND PURGE SYSTEM FOR SEMICONDUCTOR WAFERS

(76) Inventor: Shlomo Shmuelov, Yuvalim (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(21) Appl. No.: 12/282,374

(22) PCT Filed: Mar. 18, 2007
(86) PCT No.: PCT/IL07/00347

§ 371 Date: Sep. 10, 2008

Related U.S. Application Data
(60) Provisional application No. 60/783,065, filed on Mar. 17, 2006.

(51) Int. Cl. H01L 21/67; H01L 21/677

(52) U.S. Cl. 414/217; 414/805

(57) ABSTRACT

A system for storage and maintenance of semiconductor wafers or reticles under fabrication between process steps of the fabrication. The system is configured as either a stocker, an overhead transport system (OHT) or an overhead buffer (OHB with gas-purge ports which mechanically mate with a standard receptacle of a wafer/reticle carrier. A control circuit is attached to the gas-purge ports which controls gas flow into the carrier through gas purge port said Control is performed even in the absence of a communications network attached to the control circuit.

### FIELD AND BACKGROUND OF THE INVENTION

The present invention relates to semiconductor fabrication in a clean room and particularly to a storage and purging system for semiconductor wafer carriers.

Semiconductor integrated circuits are conventionally fabricated in clean rooms containing an atmosphere that is controlled to have a very low contamination content. The wafers are manufactured via chemical or other processes, and at times, are very sensitive to oxygen and humidity and other volatile contaminants. In order to avoid the potential damage to the material in process, the surrounding environment of the wafers and/or reticles is filled with a clean inert gas like nitrogen or clean dry air. In the past, the wafers/reticles were stored in gas cabinets which contained a clean environment. However, since it is difficult and expensive to maintain a clean atmosphere of large volume, such as in a clean room, semiconductor substrate wafers or masks are placed in mini-environment pods in order to protect them from the residual contamination that is still present in the clean room. U.S. Pat. Nos. 4,532,970 and 4,534,389 describe standard mechanical interfaces (SMIFs) enabling stacks of semiconductor substrate wafers having a diameter of 200 millimeters (mm) to be transported. The pod having a standard interface has a leak proof peripheral wall provided with a closable bottom access passage for inserting and removing a stack of semiconductor substrate wafers. The stack of semiconductor substrate wafers is secured to the bottom wall, the wall and the stack being moved together during insertion and withdrawal wafers having a diameter of 300 mm are also transported in mini-environment pods having a standardized front opening, known as front-opening unified pods (FOUPs). Semiconductor substrate wafers, or other substrates, typically remain for several weeks in the semiconductor fabrication unit between the various process steps. During this time, the semiconductor substrate wafers need to be maintained for instance in the mini-environment pods.

There is thus a need for, and it would be highly advantageous to have a system for storing and maintaining wafers in semiconductor carriers between process steps of the fabrication process in a controlled fashion thus improving quality of the fabrication. .

U.S. patent application publication 2005/0228530 discloses a system for manufacturing semiconductor integrated circuit (IC) devices. The system includes an operating control system, a process intermediate station, e.g. OHB, in communication with the operating control system, and a gas purge device included in the process intermediate station.

### DEFINITIONS

The terms “carrier”, “container”, “cassette” and “pod” are used hereinafter interchangeably. A “stocker” is a storage system for storing wafer carriers (e.g. FOUPs) or wafers. An “overhead transport system” (OHT) is a robotic system that transfers wafer containers from one place to another across the fabrication facility. An “overhead buffer” (OHB) stores in overhead shelves wafers and/or wafer carriers Traditionally, OHB is used for temporary storage of wafer containers. The containers are left on the OHB for any period of time, such as or until the containers are needed for further processing. The term “reticle ” “optical reticle” as used herein is typically but not limited to a photo mask used in microlithography.

### SUMMARY OF THE INVENTION

According to an embodiment of the the present invention there is provided a system for storage and maintenance of semiconductor wafers or reticles under fabrication between process steps of the fabrication. The system is configured as either a stocker, an overhead transport system (OHT) or an overhead buffer (OHB with gas-purge ports which mechanically mate with a standard receptacle of a wafer/reticle carrier. A control circuit is attached to the gas-purge ports which controls gas flow into the carrier through gas purge port said Control is performed even in the absence of a communications network attached to the control circuit. A local memory device is preferably attached to the control circuit. The local memory device stores a program accessed by the control circuit for the control of the gas flow. A communications network attached to the control circuit, transfers the program into the local memory device. The system preferably includes an input device for manually entering the program. and for manually entering commands (e.g STOP, START, NEW PROGRAM, PAUSE) to the control circuit. The gas purge ports and control circuit are preferably integrated with a previously existing storage system, a stocker, an overhead transport system (OHT) and/or overhead buffer/shelves (OHB). A reader, such as a bar code reader and/or radio frequency identification reader, reads an identifier from the carrier and the control is preferably based on the identifier. The control circuit preferably includes a processor. The processor is programmed by selecting one program based on the identifier from multiple programs stored in the local memory device. The gas-purge port preferably inserts an environmental sensor into the wafer/reticle carrier or is tapped to the output of the carrier when mating with the standard receptacle of the wafer/reticle carrier, or the wafer/reticle carrier is equipped with one or more environmental sensors and the control circuit attaches with the environmental sensors when the gas-purge port is mated with said standard receptacle. The control circuit preferably performs closed loop control based on an output of one or more of the environmental sensors. The environmental sensors include oxygen sensors, ammonia sensors, humidity sensors, gas flow sensors, particle count sensors, temperature sensors, ammonia sensors and pressure sensors. The system preferably includes a test wafer carrier which is not configured to carry a production wafer/reticle and is used to test the system. The system when integrated with a stocker, an OHB or an OHT, preferably includes an interface, e.g. SEMI E84, to facilitate negotiation between a carrier robot and the system.

According to an embodiment of the present invention there is provided a method for storing and maintaining semiconductor wafers and/or reticles under fabrication between process steps of the fabrication. The system includes a gas purge port configured into either a stocker, an overhead transport system (OHT) or an overhead buffer (OHB). The gas purge port is mechanically mated with a standard receptacle of a wafer carrier. Gas flow is controlled into the carrier through the gas purge port. A control circuit attached to the gas-purge port, controls the gas flow even in the absence of a communications network operatively attached to the control circuit.

According to an embodiment of the present invention there is provided a method for testing, monitoring and programming the system by providing a test carrier containing sensors but preferably not containing a production wafer/reticle. The test carrier is equipped with the standard receptacle. Upon mating the standard receptacle to one of the gas-purge ports, respective outputs from the sensors are transmitted through the communications network to a purge station server. The sensors include oxygen sensors, humidity sensors, gas flow sensors, ammonia sensors, particle count sensors, temperature sensors and pressure sensors.

### BRIEF DESCRIPTION OF THE DRAWINGS

The invention is herein described, by way of example only, with reference to the accompanying drawings, wherein:

FIG. 1 is a prior art drawing of a conventional stocker or a portion thereof

FIG. 2 is a simplified system drawing of a stocker/purge system according to an embodiment of the present invention;

FIG. 3 is a simplified schematic drawing of a control system, according to an embodiment of the present invention for the stocker/purge system of FIG. 2; and

FIG. 4 is a simplified system drawing of the integration of different embodiments of the present invention with a management and control system at a semiconductor fabrication facility.

### DESCRIPTION OF THE PREFERRED EMBODIMENTS

The present invention is a storage and purging system for semiconductor wafer carriers. The principles and operation of a storage and purging system for semiconductor wafer carriers according to the present invention, may be better understood with reference to the drawings and the accompanying description.

Before explaining embodiments of the invention in detail, it is to be understood that the invention is not limited in its application to the details of design and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

By way of introduction, principal intentions of the present invention are to improve quality of integrated circuit manufacture by providing systematic control of the purged mini-environment around stored wafers and/or reticles and particularly inside the wafer or reticle carrier and optional monitoring of the storage condition of the mini-environment. Another intention is to conserve space, as systems of the present invention do not require extra floor space in the clean room of the fabrication facility and standard Hobs and stockers can be replaced with storage/purge stations of the present invention that are not larger then the standard storage solutions. In different embodiments of the present invention, the gas purge functionality may be integrated into previously existing equipment, e.g stocker.

It should be noted that while the discussion herein is directed to semiconductor manufacture the principles of the present invention may be adapted for use in, and provide benefit for manufacturing other articles, e.g. MEMS devices, optical reticles that also require environmental control. The present invention may provide benefit for the use of reticles and their storage during the semiconductor manufacturing process.

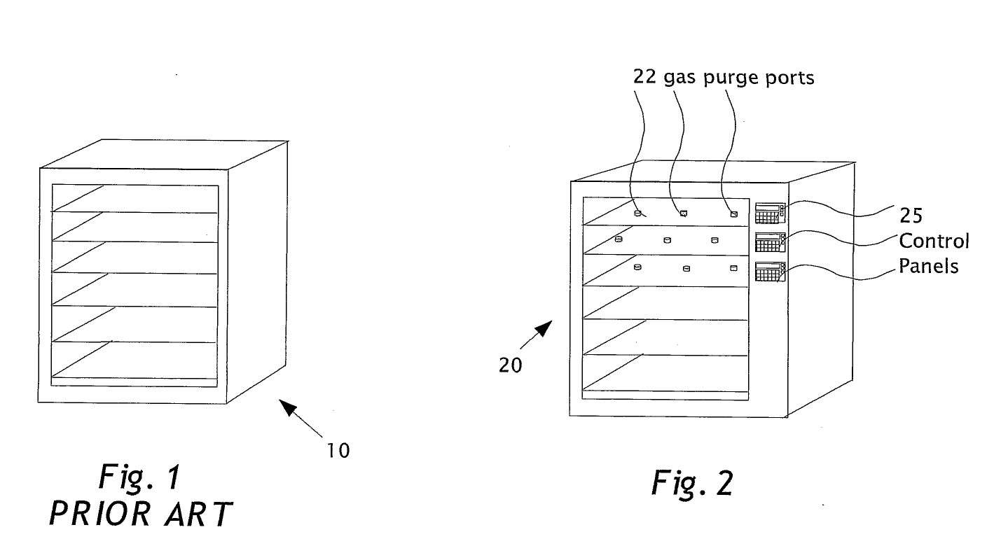

Referring now to the drawings, FIG. 1 illustrates a prior art drawing of an empty stocker 10. FIG. 2 is a simplified drawing of a stocker/purge system 20 in which shelves of stocker 10 have been equipped with gas-purge ports 22. Purge system 20 facilitates, purging gas flow to the mini-environment near the stored semiconductor wafers, typically inside a wafer or reticle carrier. Control of purge station 20 can have control of the purging function based simply on time or fixed gas flow. Purge station 20 may have sophisticated closed loop gas flow control with constant monitoring of the pressure internal to the wafer carrier and the gas quality therein. Typically, the shelf contains an electronic circuit with an optional control panel 25 with the ability to control one or more gas-purge ports 22

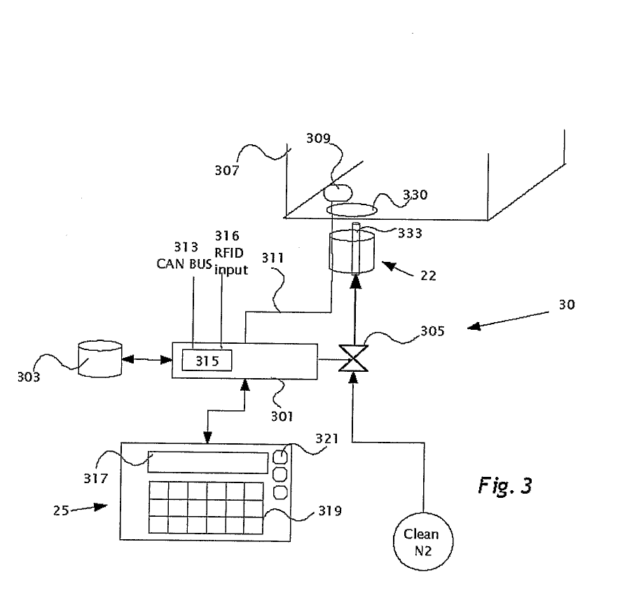

Reference is now made to FIG. 3, a simplified schematic drawing of a flow control system 30, according to an embodiment of the present invention. Purge port 22 is equipped to receive a wafer and/or reticle carrier 307 is equipped with a mating receptacle 330 which supports and preferably seals to a clean gas inlet 333. Purge port 22 optionally includes other connections, e.g wires 311. Purge flow control system 30 optionally includes one or more sensors 309. Sensor 309 optionally senses the presence or absence of wafer/reticle carrier 307 such as placement of carrier 307 in a purge port 22 and transmits a signal through wire 311 to a control circuit 301 when wafer carrier 307 is present Another sensor 309 optionally senses gas pressure inside wafer carrier 307 and returns a signal to control circuit 301 indicating the gas pressure. Other optional sensors 309 include an oxygen sensor, an ammonia sensor. a humidity sensor, an acceleration (motion) sensor, and a particle count sensor. Sensors 309 are permanently mounted inside wafer carrier 307 and are attached by wires 311 to control circuit 301 upon mating. Alternatively, sensor 309 is inserted into the wafer environment upon mating. Optionally, gas exiting from carrier 307 and/or outlet from purge station 20 is monitored. RFID reader or a bar code reader (not shown) is optionally used to identify wafer carrier 307 and/or the lot identifier of the wafers. The identifier is preferably input to electronic circuit 301 through a port 316. Electronic circuit 301 controls clean gas flow into purge ports 22 such as by controlling a valve 305. Control is either open loop or closed loop based on input 311 of sensor 309. Electronic circuit preferably includes a microprocessor 315. Microprocessor 315 is preferably attached to local memory which stores one or more programs for purging wafer carrier 307 with the clean gas. The purging programs typically define time and flow rate periods of gas flow, or define a certain required gas pressure or gas flow rate using closed loop control based on flow rate or pressure internal to wafer carrier 307. The purging program selected is preferably dependent on the identifier, e.g. lot identifier of the wafers. The program may be entered manually by using an input device, e.g keypad 319 and display 317 both part of control panel 25. The purging program may alternatively be downloaded through an external bus connection 313, e.g. CAN bus, DeviceNet or any other communications system. The program is preferably stored in memory 303 attached locally to electronic circuit 301. Alarm events are preferably logged in local memory 303. Control panel preferably also includes a local alarm 321, e.g. LED which indicates if sensor output 311 is out of specification.

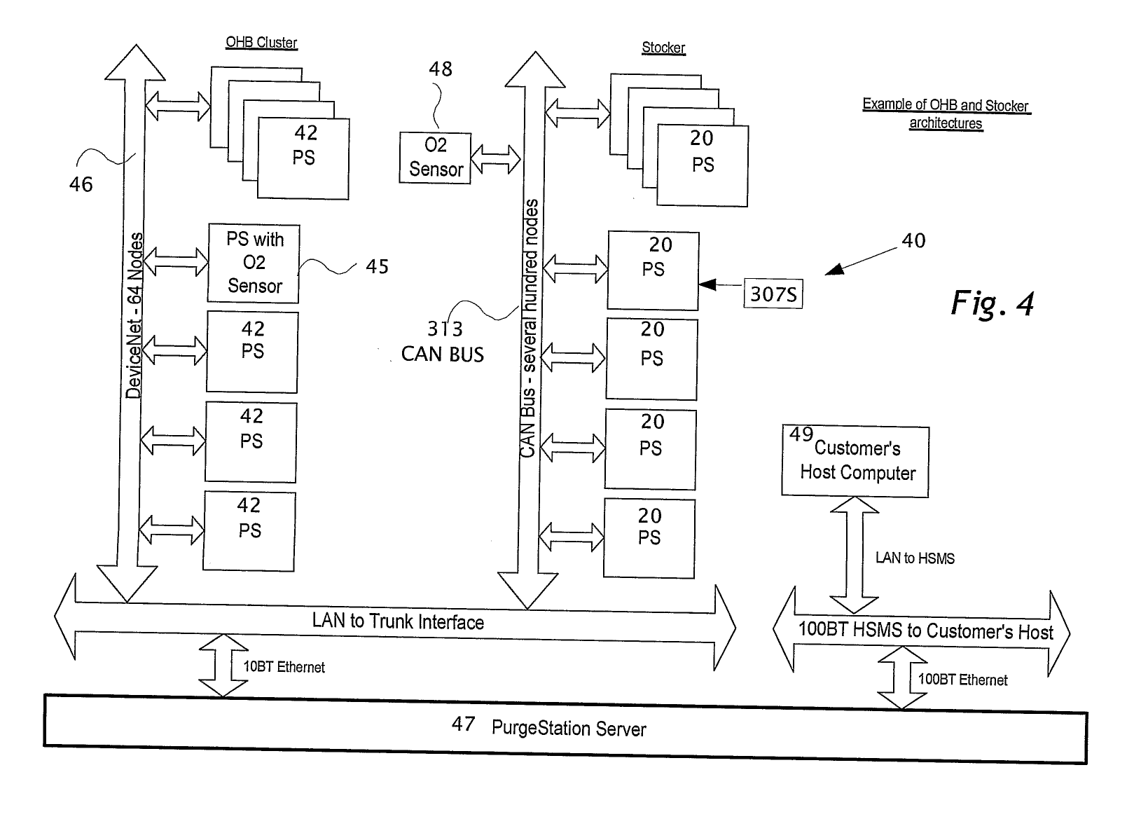

Reference is now made to FIG. 4 is simplified system drawing of the integration of different embodiments of the present invention with a management and control system 40 at a semiconductor fabrication facility. Management and control system 40 includes a purge station server 47 which is typically a computer application running on a personal computer connected to a local area network (LAN) over an Ethernet connection, e.g 100BaseT and running TCP/IP protocol. Purge station server 47 is preferable accessible to a customer host computer 49 over the LAN. Purge stations/stockers 20 are connected with purge station server 47 over a CAN bus 313. Purge stations 42 integrated into an OHB are connected to purge station server 47 using a DeviceNet bus 46. Individual purge stations 20, 42 may be controlled and monitored in a master/slave architecture or a peer-to-peer architecture. Alternative monitoring and control schemes include direct monitoring and control using analog and digital control lines or other electronic wired or wireless connections known in the art. An SEMI E84 (Specification for Enhanced Carrier Handoff Parallel I/O Interface ) interface can be added to individual purge stations 42 in order to facilitate the parallel interface negotiations between the robot and stations 42. According to embodiment of the present invention commands are sent from purge station server 47 to purge stations 20, 42. Control commands include execution related commands such as START, STOP, PAUSE, CHANGE-PROGRAM. Monitoring commands include receive sensor outputs from sensors of pressure, humidity, O₂, particle count and Flow rate.

Programs are preferably stored on purge station server 47, so that the same program is easily shared by many purge stations 20,42. However, in some embodiments of the present invention, the programs are always downloaded into local memory 303 and run locally by processor 315 so that even if a communications failure occurs between purge station server 47 to one or more purge stations 20, 42, or purge station server 47 is down, purge stations 20, 42 continue to function normally, alarms are generated locally such as through alarm LEDS 321, and alarm events and status are logged in local memory 303.

In order to improve the efficacy of the purging function performed by the present invention, additional sensors are preferably used in the fabrication facility. Additional sensors may include an oxygen sensor 48, an ammonia sensor, humidity sensors and/or particle count sensors. Additional sensors may be integrated in purge stations 20,42 such as permanently integrated with purge port 22. A OHB purge station with oxygen sensor is shown for example in block 45. Alternatively, additional sensors are integrated into special wafer/reticle carriers 307S (with or without actual wafers within). Carrier 307S equipped with additional sensors can travel in the fabrication facility in order to collect information about the fabrication equipment and environment and the information collected is sent over the communication links to a central location, e.g. host computer 49 for data collection, material and equipment tracking. When developing a new program special wafer carriers 307S with additional sensors within assist the programmer to determine program parameters, pressure, flow rate, period of gas flow, vibration, and location of the carrier etc. Once the program parameters are determined, the program itself does not require the presence of all the sensors, typically just one or two sensors per carrier 307 is required if close loop control is used. The use of special wafer carriers 307S hence improves the programs and reduces overall cost of purge systems of the present invention. Communications with the sensors can be wired, or wireless using known wireless standards such as ZigBee or IEEE 802.11x

Alternatively, additional sensors for pressure, temperature, acceleration, motion, gas and humidity concentrations inside carrier 307, may be used during and after the purge process to collect information. The information is analyzed and reported along with a specific carrier 307 identifier and/or and a lot identifier of the wafers. The collected information can be used by facility personnel to improve carriers 307 and/or the purging process and to provide traceability of carrier 307 and the lot.

While the invention has been described with respect to a limited number of embodiments, it will be appreciated that many variations, modifications and other applications of the invention may be made.

What is claimed is:

1. A system for storage and maintenance of semiconductor wafers and/or reticles under fabrication between process steps of the fabrication, the system comprising:
(a) a plurality of gas-purge ports, wherein each of said gas-purge ports is configured to mechanically mate with a standard receptacle of a wafer/reticle carrier;
(b) a control circuit attached to said gas-purge ports, said control circuit controlling gas flow into said carrier through one of said gas purge ports wherein said controlling is performed even in the absence of a communications network operatively attached to said control circuit,
wherein the system is configured as selectably either a stocker, an overhead transport system (OHT) or an overhead buffer (OHB).

2. The system, according to claim 1, further comprising:
(c) a local memory device attached to said control circuit, wherein said local memory device stores a program accessed by said control circuit for said controlling said gas flow.

3. The system, according to claim 2, further comprising:
(c) said communications network operatively attached to said control circuit, wherein said communications network transfers said program into said local memory device.

4. The system, according to claim 2, further comprising:
(d) an input device for manually entering said program.

5. The system, according to claim 1, further comprising:
(d) an input device for manually entering commands to said control circuit.

6. The system, according to claim 1, wherein said gas purge ports and control circuit are integrated with a previously existing storage system selected from the group consisting of: a stocker, an overhead transport system (OHT) and overhead buffer/shelves (OHB).

7. The system, according to claim 1, further comprising:
(c) a reader which reads an identifier from said carrier, wherein said controlling is based on said identifier.

8. The system, according to claim 7, wherein said control circuit includes a processor, wherein said processor is programmed by selecting one program based on said identifier from a plurality of programs stored in said local memory device.

9. The system, according to claim 7, wherein said reader is selected from the group consisting of a bar code reader and radio frequency identification reader.

10. The system, according to claim 1, wherein at least one of said gas-purge ports inserts at least one environmental sensor into said wafer/reticle carrier when mating with said standard receptacle of said wafer/reticle carrier.

11. The system, according to claim 1, wherein the output port of said wafer/reticle carrier is monitored, when mating with said standard receptacle of said wafer/reticle carrier.

12. The system, according to claim 1, wherein said wafer/reticle carrier is equipped with at least one sensor for sensing at least one of the environment, placement of said wafer/reticle carrier or motion of said wafer/reticle carrier.

13. The wafer/reticle carrier of claim 12, equipped with said at least one sensor.

14. The system, according to claim 12, wherein said control circuit operatively attaches with said at least one environmental sensor when said gas-purge port is mated with said standard receptacle.

15. The system, according to claim 12, wherein said control circuit performs said controlling with closed loop control based on an output of said at least one sensor.

16. The system, according to claim 12, wherein said at least one environmental sensor is selected from the group consisting of: oxygen sensors, humidity sensors, gas flow sensors, particle count sensors, temperature sensors, placement, motion and pressure sensors.

17. The system, according to claim 12, wherein said wafer/reticle carrier is not configured to carry a production wafer, whereby said wafer/reticle carrier is used to test the system,

18. The system, according to claim 1, further comprising an interface to facilitate negotiation between a carrier robot and the system.

19. The system, according to claim 18, wherein said interface is a SEMI E84 Specification for Enhanced Carrier Handoff Parallel I/O Interface.

20. A method for storing and maintaining semiconductor wafers under fabrication between process steps of the fabrication, the method comprising the steps of:
(a) providing a system configured into selectably either a stocker, an overhead transport system (OHT) or an overhead buffer (OHB), wherein the system includes a gas purge port;
(b) mechanically mating said gas-purge port with a standard receptacle of a wafer carrier;
(c) controlling gas flow into said carrier through said gas purge port with a control circuit attached to said gas-purge port, wherein said controlling is performed even in the absence of a communications network operatively attached to said control circuit

21. A method for testing, monitoring and programming the system according to claim 1, the method comprising the steps of:
(a) providing a test carrier containing a plurality of sensors but not containing a production wafer/reticle, wherein the test carrier is equipped with the standard receptacle;
(b) upon mating the standard receptacle to one of said gas-purge ports, transmitting respective outputs from said sensors through said communications network to a purge station server.

22. The method, according to claim 21, wherein the sensors are selected from the group consisting of: oxygen sensors, ammonia sensors, humidity sensors, motion and location, gas flow sensors, particle count sensors, temperature sensors and pressure sensors.
